(19) United States
(12) Patent Application Publication
(10) Pub. No.: US 2026/0096404 A1
(43) Pub. Date: Apr. 2, 2026

(54) METHOD OF MANUFACTURING AN ELECTRONIC DEVICE COMPRISING DOPED SILICON ELECTRICAL CONTACTING ELEMENTS

(71) Applicant: STMicroelectronics International N.V., Geneva (CH)

(72) Inventors: Sylvain JOBLOT, Domarin (FR); Laurent GAY, Lumbin (FR); Benjamin VIANNE, LE CHEYLAS (FR); Magali GREGOIRE, Crolles (FR); Alexis FARCY, Aiton (FR)

(73) Assignee: STMicroelectronics International N.V., Geneva (CH)

(21) Appl. No.: 19/337,221

(22) Filed: Sep. 23, 2025

(30) Foreign Application Priority Data
Sep. 27, 2024 (FR) FR2410382

(51) Int. Cl. H01L 21/768; H01L 21/265; H01L 23/522; H01L 23/532; H10F 77/00

(52) U.S. Cl. CPC H10W 20/056; H10P 30/204; H10P 30/208; H10W 20/42; H10W 20/4451; H10F 77/933

(57) ABSTRACT

A method of manufacturing an electronic device includes a) forming, in a semiconductor substrate first doped regions of a first type and second doped regions of a second type; b) depositing a dielectric layer on the upper surface of the substrate; c) after step b), forming first and second openings in dielectric layer to expose the first and second regions; d) implanting non-doping ions in the second regions to amorphize an upper portion of the second regions; e) after steps c) and d), filling the first and second openings with doped monocrystalline or polycrystalline silicon of the first type; and f) performing a thermal anneal of the device to recrystallize said upper portion of the second regions and generate crystal defects in a space charge region of a p-n junction formed at the interface between the vias and the second regions.

### PRIORITY CLAIM

This application claims the priority benefit of French Application for Patent No. FR2410382, filed on Sep. 27, 2024, the content of which is hereby incorporated by reference in its entirety to the maximum extent allowable by law.

### TECHNICAL FIELD

The present disclosure generally concerns electronic devices and, in particular, the manufacturing of an electronic device comprising doped silicon electrical contacting elements.

### BACKGROUND

United States Patent Application Publication No. 2024/0204029 (corresponding to European patent application EP4386850), incorporated herein by reference, describes an example of an image sensor comprising a plurality of photodetection pixels formed inside and on top of a semiconductor substrate, and an interconnection network coating a surface of the semiconductor substrate, the interconnection network comprising a level of doped silicon conductive vias in contact, by their lower surface, with the photodetection pixels.

There is a need in the art to improve known electronic devices comprising doped silicon electrical contacting elements.

### SUMMARY

In an embodiment, a method of manufacturing an electronic device comprises the following steps: a) forming, in an upper surface side of a semiconductor substrate, first doped regions of a first conductivity type and second doped regions of a second conductivity type opposite to the first type; b) after step a), depositing a dielectric layer on the upper surface of the substrate; c) after step b), forming first and second openings in dielectric layer to respectively expose the first and the second regions of the substrate; d) implanting non-doping ions in the second regions to amorphize an upper portion of the second regions; e) after steps c) and d), filling the first and second openings with doped monocrystalline or polycrystalline silicon of the first conductivity type to form contacting vias on the first and second regions; and f) performing a thermal anneal of the device to recrystallize said upper portion of the second regions.

According to an embodiment, at the end of step f), crystal defects are generated in a space charge region of a p-n junction formed at the interface between the vias and the second regions.

According to an embodiment, at the end of step f), crystal defects are generated outside and within 100 nm of the space charge region.

According to an embodiment, step d) is implemented after step c).

According to an embodiment, step d) is carried out between step a) and step b).

According to an embodiment, step f) is implemented after step e).

According to an embodiment, the method further comprises a step of deposition of an electrically-conductive layer made of doped monocrystalline or polycrystalline silicon of the first conductivity type, on top of and in contact with the surface of the vias opposite to the first and to the second regions of the substrate.

According to an embodiment, the non-doping ions are a combination of at least one among germanium, argon, carbon, or silicon ions.

According to an embodiment, the substrate is made of silicon.

According to an embodiment, the thermal anneal is performed at temperature in the range from 800° C. to 1,000° C.

In an embodiment, an electronic device comprises: a semiconductor substrate; on the upper surface side of the substrate, first doped regions of a first conductivity type and second doped regions of a second conductivity type, opposite to the first type; a dielectric layer coating the upper surface of the substrate; and doped monocrystalline or polycrystalline silicon vias of the first conductivity type extending through the dielectric layer to make electrical contact on the first and second regions.

In an embodiment, an image sensor comprises the electronic device as defined above.

According to an embodiment, the image sensor is configured to be illuminated on its front surface, that is, on the side of the substrate in contact with the vias.

Another embodiment provides a system comprising first and second vertically stacked image sensors, wherein: the first image sensor is a sensor as defined above, configured to be illuminated on its rear surface, that is, on the side of the substrate opposite to the vias; and the second image sensor is arranged on the front surface side of the first sensor.

According to an embodiment, the first image sensor is a visible image sensor and the second image sensor is an infrared image sensor.

### BRIEF DESCRIPTION OF THE DRAWINGS

The foregoing features and advantages, as well as others, will be described in detail in the rest of the disclosure of specific embodiments given as an illustration and not limitation with reference to the accompanying drawings, in which:

FIG. 1 is a cross-section view, partial and simplified, of an image acquisition device according to an embodiment of the present disclosure;

FIG. 2 is a more detailed cross-section view of a portion of the image acquisition device of FIG. 1;

FIG. 3A, FIG. 3B, FIG. 3C, FIG. 3D, FIG. 3E, FIG. 3F, and FIG. 3G are cross-section views showing steps of a method of manufacturing the device of FIG. 1 and of FIG. 2 according to an embodiment of the present disclosure; and

FIG. 4A, FIG. 4B, FIG. 4C, FIG. 4D, and FIG. 4E are cross-section views showing steps of a method of manufacturing the device of FIG. 1 and of FIG. 2 according to another embodiment of the present disclosure.

### DETAILED DESCRIPTION

Like features have been designated by like references in the various figures. In particular, the structural and/or functional features that are common among the various embodiments may have the same references and may dispose identical structural, dimensional and material properties.

For clarity, only those steps and elements which are useful to the understanding of the described embodiments have been shown and are described in detail. In particular, only steps enabling to form conductive vias, made of doped silicon, for making electrical contact with doped semiconductor regions of a conductive substrate, have been detailed hereafter. The forming of the other elements of the electronic device and for example of an image acquisition device is not detailed. For example, the forming of pixels, of photoreceptors, and of the associated readout circuits, has not been detailed, the described embodiments being compatibles with usual implementations of these elements or the forming of these elements being within the abilities of those skilled in the art based on the indications of the present disclosure.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following description, where reference is made to absolute position qualifiers, such as “front”, “back”, “top”, “bottom”, “left”, “right”, etc., or relative position qualifiers, such as “top”, “bottom”, “upper”, “lower”, etc., or orientation qualifiers, such as “horizontal”, “vertical”, etc., reference is made unless otherwise specified to the orientation of the drawings in a normal position of use.

Unless specified otherwise, the expressions “about”, “approximately”, “substantially”, and “in the order of” signify plus or minus 10%, preferably of plus or minus 5%.

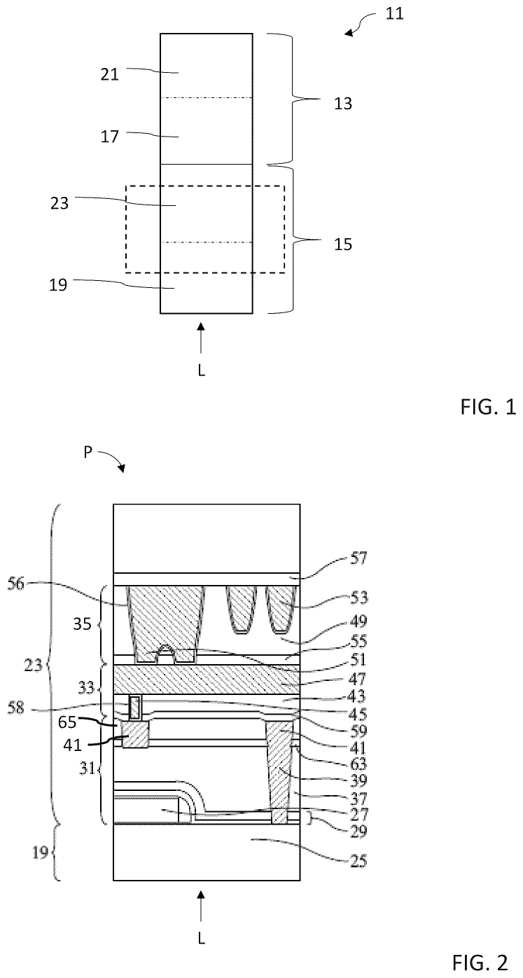

FIG. 1 is a cross-section view, partial and simplified, of an example of an image acquisition device 11 according to an embodiment.

Image acquisition device 11 corresponds, for example, to the assembly of a first structure 13 corresponding to a first image sensor, and of a second structure 15 corresponding to a second image sensor. The first image sensor is, for example, an infrared image sensor and the second image sensor is, for example, a visible image sensor, for example a color image sensor. In this example, the two infrared and visible sensors 13 and 15 are stacked one on top of the other.

As an example, each of sensors 13 and 15 comprises an assembly of pixels formed inside and on top of a semiconductor substrate. Each pixel comprises, for example, a photoreceptor, for example a photodiode, and a circuit for reading from the photoreceptor. Thus, sensor 13 comprises an assembly of pixels 17 and sensor 15 comprises an assembly of pixels 19. Further, each of sensors 13 and 15 comprises a network of interconnection of the sensor pixels. Sensor 13 thus comprises an interconnection network 21 and a sensor 15 comprises an interconnection network 23. In the shown example, infrared sensor 13 is arranged on visible sensor 15. The lower surface of the assembly of pixels 17 of sensor 13 is in contact with the upper surface of the interconnection network 23 of sensor 15. The interconnection network 21 of infrared sensor 13 is arranged on the upper surface side of the assembly of pixels 17. The assembly of pixels 19 of visible sensor 15 is arranged on the lower surface side of interconnection network 23.

Device 11 is, in the example illustrated in FIG. 1, intended to be illuminated on its lower surface. An incident radiation to be measured by the device is represented by an arrow L on the figure. The visible radiation is absorbed by the photodetectors of the pixels of sensor 15, which enables to acquire an image in the wavelength range of the visible spectrum. Sensor 15 is however substantially transparent to infrared radiation. This radiation is absorbed by the photodetectors of sensor 13, which enables to acquire an image in the wavelength range of the infrared and near-infrared spectrum, for example of the short-wave infrared (SWIR) spectrum, for example in the waveband ranging from 0.7 to 2.5 μm.

In each of sensors 13 and 15, the sensor pixels are, for example, arranged in an array of rows and columns.

FIG. 2 is a cross-section view, more detailed, of a portion of the image acquisition device 11 of FIG. 1. More specifically, FIG. 2 shows in further detail the portion of the device 11 of FIG. 1, surrounded by dotted lines in FIG. 1, that is, a portion of interconnection network 23 and a portion of the assembly of pixels 19 of sensor 15.

In FIG. 2, a portion of a pixel P of sensor 15 is shown. In the example shown in FIG. 2, the portion of the pixel P is configured to be illuminated on its lower surface. An incident radiation to be measured by the pixel is represented by an arrow L on the figure. As an example, each pixel P comprises a photodetector, not shown, formed inside and on top of a substrate 25. Each photodetector is, for example, connected to a readout circuit comprising transistors comprising gates 27, formed on substrate 25. Gates 27 are, for example, made of polysilicon, for example doped. As an example, gates 27 are made of N-type doped polysilicon, for example doped with phosphorus atoms or with arsenic atoms. Substrate 25 is, for example, made of a semiconductor material, for example of silicon, for example of single-crystal silicon.

Interconnection network 23 is formed of a stack or network of electrically-conductive levels and electrically-insulating levels having interconnection elements formed therein. In the example of FIG. 2, interconnection network 23 comprises three levels: a first level 31, called lower level, coating the upper surface of substrate 25 and the upper surface of gates 27; a second level 33 coating first level 31, for example on top of and in contact with the upper surface of first level 31; and a third level 35 coating second level 33, for example on top of and in contact with the upper surface of second level 33.

In practice, interconnection network 23 may comprise a number of levels different from three, for example greater than three.

As an example, each level comprises one or a plurality of electrically-insulating layers having electrically-conductive tracks and electrically-conductive vias formed therein.

Lower level 31 thus comprises, for example, dielectric layers 29, 37, 63, and 65. Lower level 31 further comprises electrically-conductive vias 39 and electrically-conductive tracks 41. In the example of FIG. 2, vias 39 run through dielectric layers 29 and 37 and electrically-conductive tracks 41 run through dielectric layers 63 and 65. Similarly, second level 33 comprises, for example, an electrically-insulating layer 43 having electrically-conductive vias 45 and electrically-conductive tracks 47 formed therein. Third level 35 comprises, for example, an electrically-insulating layer 49 having electrically-conductive vias 51 and electrically-conductive tracks 53 formed therein.

As an example, vias 39 are in contact, by their lower surface, with substrate 25 or with the gates 27 of the transistors of the readout circuits of the pixels, and, by their upper surface, with the lower surface of tracks 41. Vias 45 are, for example, in contact, by their lower surface, with the upper surface of tracks 41, and, by their upper surface, with the lower surface of tracks 47. Vias 51 are, for example, in contact, by their lower surface, with the upper surface of tracks 47, and, by their upper surface, with the lower surface of tracks 53.

In the example of FIG. 2, dielectric layer 29 covers the upper surface of substrate 25 and gates 27. As an example, layer 29 is formed of a nitride and/or of an oxide, for example made of a silicon nitride (SiₓN_{y}), a silicon carbonitride (SiCₓN_{y}) and/or a silicon dioxide (SiO₂). As an example, layer 29 comprises a first sub-layer on top of and in contact with the upper surface of substrate 25 and the upper surface of gates 27 and a second sub-layer on top of and in contact with the upper surface of the first sub-layer. The first sub-layer is, for example, made of silicon dioxide. The second sub-layer is, for example, made of silicon nitride.

Layers 37, 43, 49, and 65 are, for example, made of silicon dioxide (SiO₂) and/or silicon nitride (SiₓN_{y}) and/or silicon carbonitride (SiCₓN_{y}). As an example, layers 37, 43, 49, and 65 each correspond to a stack of the above-mentioned materials.

Vias 45 and 51 and tracks 47 and 53 are, for example, made of metal, for example of transition metal, for example made of tungsten, copper, cobalt, or ruthenium. As an example, vias 45 are made of tungsten, and vias 51 and tracks 53 and 47 are made of copper.

As an example, the levels of interconnection network 23 are separated by encapsulation layers. In the example shown in FIG. 2, an encapsulation layer 59 thus covers the first level 31, an encapsulation layer 55 covers the second level 33, and an encapsulation layer 57 covers the third level 35 of interconnection network 23. Encapsulation layers 59, 55, and 57 are, for example, made of an electrically-insulating material enabling to form a barrier to the diffusion of copper or of certain ions into the silicon of layers 65, 43, and 49. As an example, encapsulation layers 55 and 57 are made of a material different from copper, for example made of silicon nitride or silicon carbonitride (SiCN). As an example, layer 59 is made of a dielectric material, for example made of nitride, for example made of silicon nitride.

Similarly, vias 45 and 51 and tracks 53 and 47 are, for example, surrounded by a layer enabling to form a barrier to the diffusion of the material of the vias, for example made of copper or tungsten, into the silicon dioxide of layers 43 and 49. In the shown example, vias 51 and tracks 53 are, for example, surrounded, for example encapsulated, by a barrier layer 56 and via 45 is, for example, surrounded by a barrier layer 58. Barrier layer 56 is, for example, made of tantalum nitride (TaN) and barrier layer 58 is, for example, made of titanium and/or titanium nitride (TiN).

As an example, the conductive tracks 41 of level 31 are arranged on top of and in contact with a layer 63. Layer 63 is, for example, made of a dielectric material, for example made of nitride, for example made of silicon nitride.

The transparency of sensor 15 to the radiation captured by sensor 13 is provided by the transparency of all the elements described hereabove and more particularly of all photodetectors 19 and of interconnection network 23.

As an example, the assembly of pixels 19 of sensor 15 is transparent to infrared radiation. Interconnection network 23 may, however, comprise electrical connection elements (tracks and/or electrical connection vias), for example metallic, that are non-transparent to infrared radiation.

In this example, although this is not shown in FIG. 2, it is provided offset to the periphery of pixels P, the tracks and the vias of the upper levels, levels 33 and 35 in the example of FIG. 2, of interconnection network 23. This enables to leave a passage transparent to infrared radiation opposite a central portion of pixels P.

The vias 39 of the lower level 31 of interconnection network 23 enable to make electrical contact with the upper surface of gates 27 as well as at different locations at the surface of substrate 25, for example on sense nodes of pixels P. Their offsetting to the periphery of pixels P is thus not possible.

According to an embodiment, it is provided to form the vias 39 of the first level of interconnection network 23 with doped monocrystalline or polycrystalline silicon, which has the advantage of being transparent to infrared radiation. The vias 39 are formed, for example, by an epitaxy process to obtain doped monocrystalline silicon vias, or by a deposition process of doped polycrystalline silicon to obtain doped polycrystalline silicon vias. Electrically-conductive tracks 41 are, for example, made of the same material as vias 39, for example made of doped monocrystalline or polycrystalline silicon of the same conductivity type as vias 39.

This enables to improve the transparency of interconnection network 23 to infrared radiation opposite pixels P, and thus to increase the luminous flux received by infrared sensor 13.

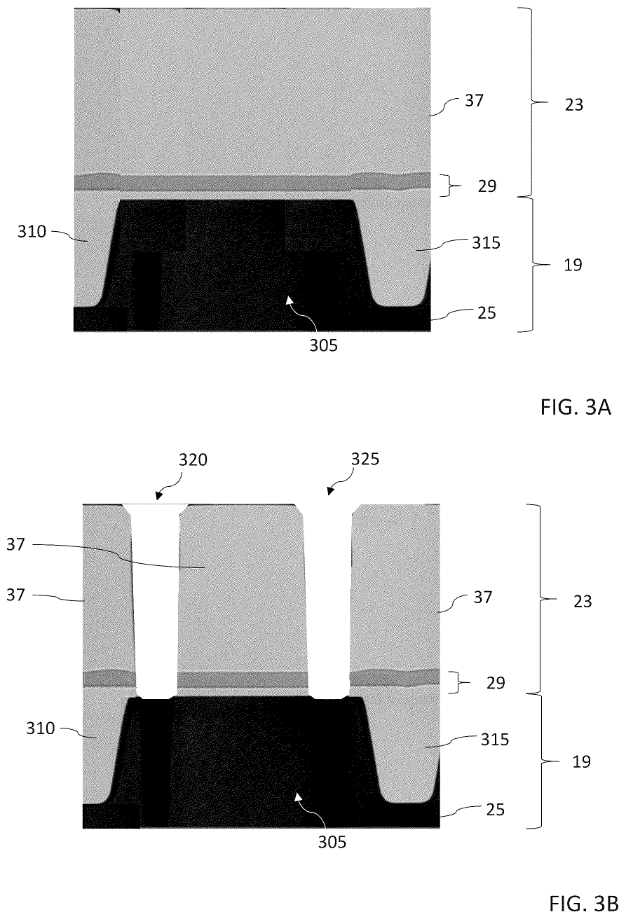

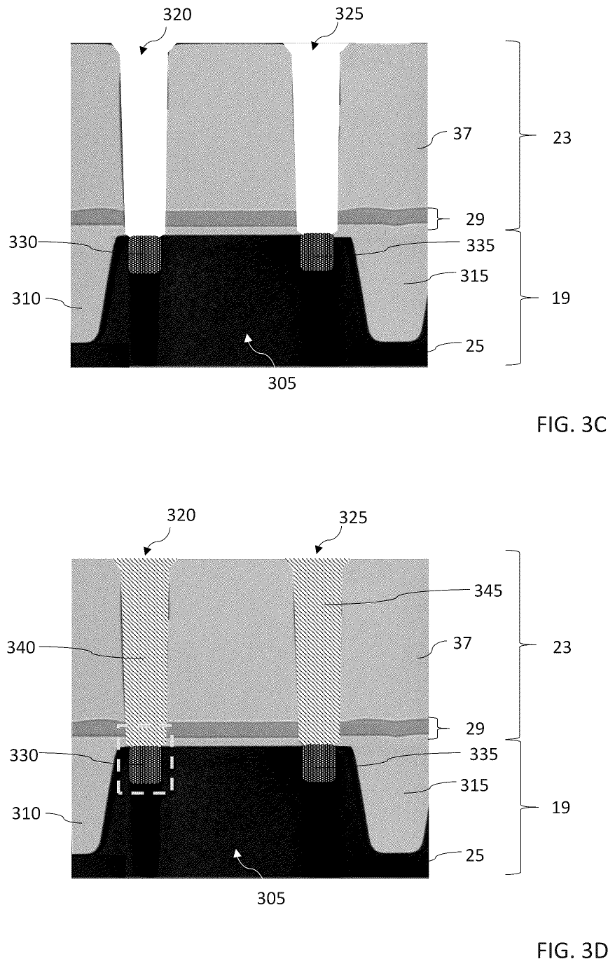

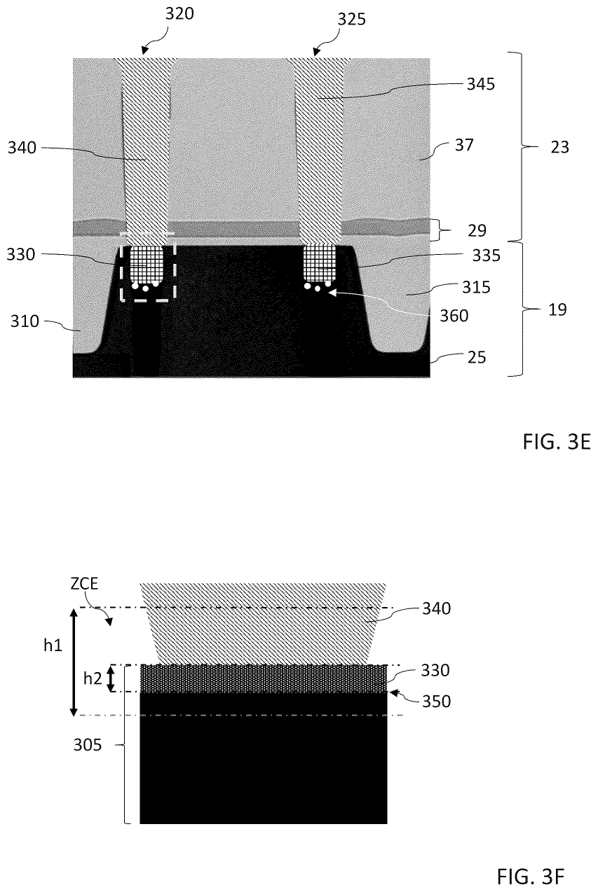

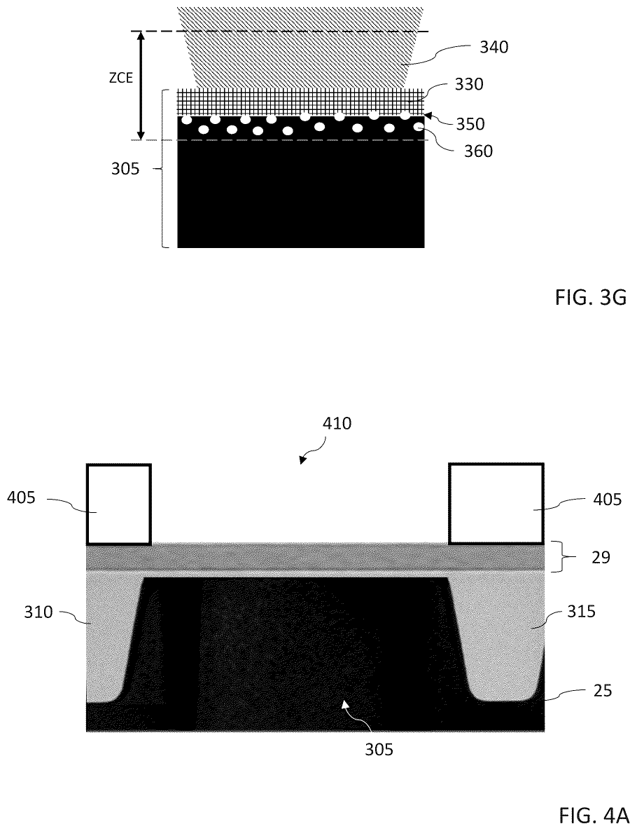

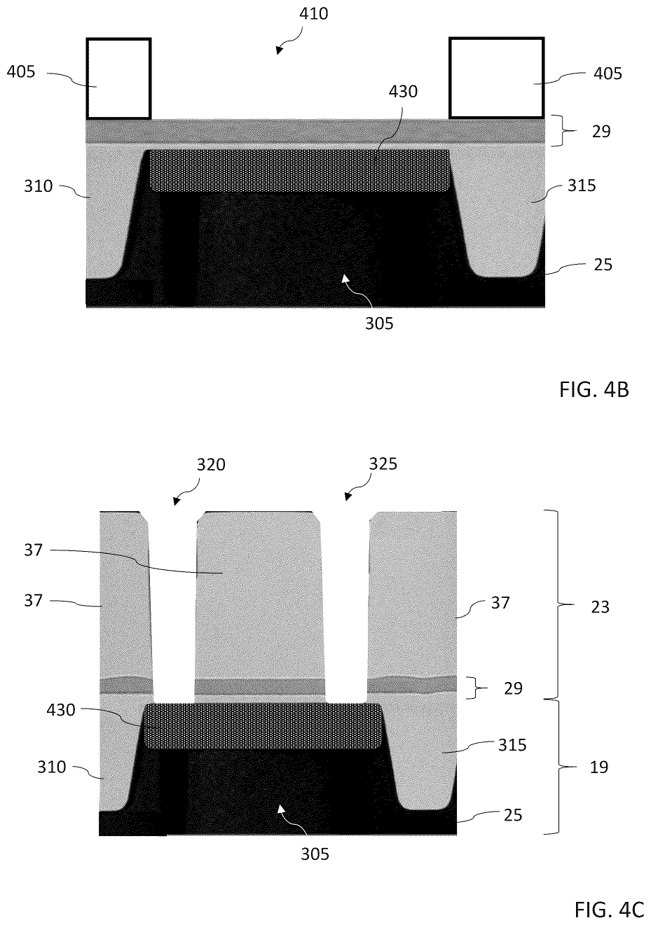

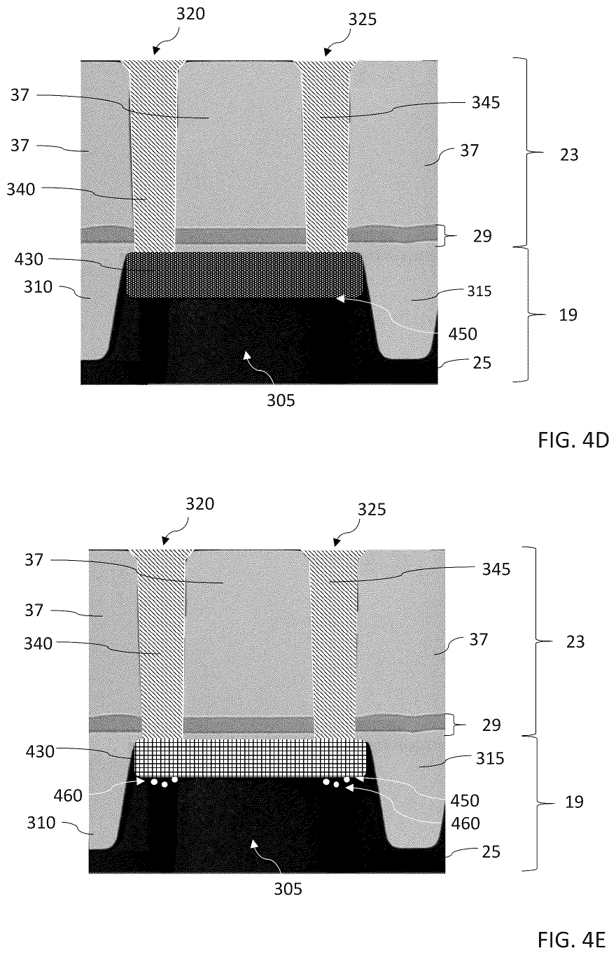

In the device of FIGS. 1 and 2, first vias 39 (referred to as 39A in the description for clarity purposes, without reference to the figures) are intended to ensure the making of an electrical contact on first doped regions of substrate 25 (not detailed in the drawings) of a first conductivity type, for example type N, and second vias 39 (referred to as 39B in the description for clarity purposes, without reference to the figures) are intended to ensure the making of an electrical contact on second regions of substrate 25 (not detailed in FIGS. 1 and 2 and corresponding to the doped regions 305 of FIGS. 3A to 3G and 4A to 4E), of a second conductivity type opposite to the first conductivity type, for example type P, for example doped with boron atoms by means of bore ions or of boron difluoride (BF2).

As an example, each first via 39A is in direct contact, by its lower surface, with a first doped region of substrate 25 of first conductivity type, and each second via 39B is in direct contact, by its lower surface, with a second doped region of substrate 25 of the second conductivity type.

To ensure a good electrical connection between vias 39 and the underlying regions of the substrate, a possibility is to form the first vias 39A with doped monocrystalline or polycrystalline silicon of the first conductivity type and to form the second vias 39B with doped monocrystalline or polycrystalline silicon of the second conductivity type. This however makes the method of manufacturing the device relatively complex, since two distinct steps of forming of doped monocrystalline or polycrystalline silicon respectively of the first conductivity type and of the second conductivity type are then necessary to respectively form the first and the second vias 39B.

According to an aspect of an embodiment, all vias 39 are made of doped monocrystalline or polycrystalline silicon of a same conductivity type. This enables all vias 39 to be simultaneously formed during a same doped monocrystalline or polycrystalline silicon forming step, thus limiting the complexity of the method of manufacturing the device.

For example, all vias 39 are made of doped monocrystalline or polycrystalline silicon of the first conductivity type, that is, type N in the described example.

In this case, each first via 39A is in contact with a first underlying region of substrate 25, of the same conductivity type as the via. An ohmic contact is thus formed between the via and the underlying semiconductor region of the substrate. A current flowing through the electrical contact is then, for example, proportional to the voltage applied between via 39A and the first underlying region.

Each second via 39B is in contact with a second underlying region of substrate 25, of a conductivity type opposite to that of the via. A p-n junction is then formed at the interface between via 39B and the underlying region of substrate 25. The presence of such a junction tends to increase drastically the contact resistance between the via 39B and area 305 and to suppress its ohmic behavior.

According to an aspect of the described embodiments, to limit the degradation of the resistance of the electrical contact between the second vias 39B and the second doped regions of substrate 25, it is provided to generate, by means of a step of implantation of neutral ions followed by a crystallization anneal, defects in the space charge region of the p-n junction formed between via 39B and the substrate, to degrade the p-n junction and favor the appearance of a leakage current in the junction.

FIGS. 3A to 3G illustrate successive steps of an example of a method of manufacturing the device 11 described in relation with FIG. 1 and FIG. 2 according to an embodiment of the present disclosure.

Certain elements of FIGS. 3A to 3G correspond to elements of FIG. 1 or of FIG. 2. These elements are designated with the same references and will not be described again in detail.

FIGS. 3A to 3G illustrate the manufacturing of a portion only of the elements of the device 11 of FIGS. 1 and 2. FIGS. 3A to 3G more particularly show the forming of second doped monocrystalline or polycrystalline silicon vias 39B, of the first conductivity type, that is, type N in the described example, in contact with a second region 305 of semiconductor substrate 25, doped with the second conductivity type, that is, type P in this example.

FIG. 3A shows an example of an initial structure for the implementation of a method of manufacturing the device 11 of FIG. 1.

In the example of FIG. 3A, a second doped region 305 of substrate 25, of the second conductivity type, is shown. Region 305 is, for example, surrounded by a first insulating trench 310 and by a second insulating trench 315. Insulating trenches 310 and 315 are for example shallow trench insulation (STI) trenches. Insulating trenches 310 and 315 are formed in substrate 25, from the upper surface of substrate 25, and vertically extend towards the lower surface of substrate 25. Region 305 and insulating trenches 310 and 315 are, for example, covered by dielectric layer 29. As an example, dielectric layer 29 is in contact, by its lower surface, with the upper surface of region 305 and of insulating trenches 310 and 315. Dielectric layer 29 is, for example, covered by dielectric layer 37. As an example, dielectric layer 37 is in contact, by its lower surface, with the upper surface of dielectric layer 29. As an example, dielectric layer 29 comprises a first sub-layer of silicon dioxide covered by a second sub-layer of silicon nitride. For example, the first sub-layer has a thickness in the range from 4 nm to 20 nm and the second sub-layer has a thickness in the range from 35 nm to 150 nm. As an example, the first sub-layer has a thickness of approximately 10 nm and the second sub-layer has a thickness of approximately 40 nm. Dielectric layer 37 has, for example, a thickness in the range from 200 nm to 550 nm. As an example, the dielectric layer 37 has a thickness of approximately 400 nm.

As a variant, insulating trenches 310 and 315 may be omitted.

The steps of manufacturing substrate 25 and of forming layers 29 and 37 and insulating trenches 310 and 315 are not detailed. The described embodiments are compatible with usual embodiments of these elements.

FIG. 3B shows the structure obtained after a step of local etching of openings intended to contain vias 39, from the upper surface of dielectric layer 37.

In the shown example, a first opening 320 and a second opening 325 are formed. Openings 320 and 325 run through layers 37 and 29 and emerge onto the upper surface of the doped region 305 of substrate 25.

The etch step is, for example, carried out by a dry etching, for example by plasma etching.

FIG. 3C shows the structure obtained after a step of ion implantation in region 305 of substrate 25, opposite openings 320 and 325.

During this step, ions are implanted in an upper portion of region 305 of substrate 25 opposite openings 320, 325. In the example of FIG. 3C, the ions are implanted, through first opening 320 and through second opening 325. The ion implantation allows to create crystal defects and to amorphize or partially amorphize a first area 330 and a second area 335 in an upper portion of region 305, respectively opposite first opening 320 and second opening 325. For example, the implantation results in that, after a later step of annealing described below, dislocations are generated and result in partially amorphizing the first area 330 and the second area 335. The ion implantations may further induce, after annealing, the formation of deep defects, in region 305 of substrate 25, below first area 330 and second area 335. In this example, dielectric layer 37 is used as a mask during the implantation, and enables to locally perform the surface amorphization of substrate 25 opposite openings 320, 325. According to an aspect of the described embodiments, during the implantation step, ions are further implanted in the dielectric layer 37 and remain in the dielectric layer 37.

An ion implantation energy is, for example, in the range from 1 keV to 15 keV.

The implanted ions are, for example, neutral ions, that is, non-doping for the semiconductor material of substrate 25, such as not N-type or P-type, for example germanium, carbon, silicon, argon ions, or a combination of these elements. An advantage of using neutral ions is that this enables to decrease the probability of causing a charge carrier recombination and to modify the doping of region 305 of substrate 25 or of vias 39.

A chemical cleaning step using a wet etching solution can optionally be implemented after the openings 320, 325 have been made and before the openings are filled to form the vias. Preferably, this chemical cleaning step is implemented after the ion implantation step. Alternatively, the chemical cleaning step can be implemented before the ion implantation step.

FIG. 3D shows the structure obtained after a step of forming of a via 340 and of a via 345 respectively in the first opening 320 and in the second opening 325.

Via 340 and via 345 are made of doped monocrystalline or polycrystalline silicon of the first conductivity type, that is, type N in the described example. Vias 340 and 345 enable to make electrical contact with the underlying region 305. Vias 340 and 345 each correspond to a second via 39 of the device of FIGS. 1 and 2.

Via 340 and via 345 are, for example, formed by a method of non-local deposition of doped monocrystalline or polycrystalline silicon into openings 320 and 325 and on the upper surface of dielectric layer 37, followed by a chemical-mechanical polishing step to keep the monocrystalline or polycrystalline silicon only in openings 320, 325 so as to form vias 340, 345.

In the example of FIG. 3D, a lower surface of via 340 is in contact with an upper surface of first area 330 and a lower surface of via 345 is in contact with an upper surface of second area 335.

FIG. 3E shows the structure obtained after a step of thermal anneal, for example of rapid thermal processing or in an oven.

During the thermal anneal step, the first area 330 and the second area 335 of substrate 25 recrystallize. During this step, crystal defects 360 form at the interface between each of areas 330, 335, and under each of areas 330, 335.

The thermal anneal step is, for example, carried out at a temperature in the range from 750° C. to 1,100° C. and preferably carried out at a temperature in the range from 800° C. to 1,000° C. The duration of the thermal recrystallization anneal is, for example, in the range from 1 second to several minutes, for example in the range from 1 second to 30 minutes. The anneal temperature is, for example, sufficiently high to recrystallize the first area 330 and the second area 335 and sufficiently low for crystal defects to remain under areas 330 and 335, in the space charge region of the p-n junction formed between each of areas 330, 335 and the overlying via 340, 345 or in proximity of the space charge region.

FIG. 3F is a cross-section view, more detailed, of a portion of the structure of FIG. 3D. More particularly, FIG. 3F shows an enlarged view of a portion of FIG. 3D delimited by a frame in dashed lines in FIG. 3D.

FIG. 3F shows the p-n junction formed between via 340 and the first area 330 of region 305.

Via 340 is made of doped monocrystalline or polycrystalline silicon of the first conductivity type, that is, type N in the described example, and region 305 is formed in a doped semiconductor material of the second conductivity type, that is, type P in the described example. The contact between via 340 and region 305 thus forms a p-n junction and a space charge region (SCR) creates, in via 340 and in region 305, close to the interface between via 340 and region 305. The charge carrier concentration in the SCR is, for example, relatively low. The doping of via 340, the doping of region 305, and the temperature of the thermal recrystallization anneal of the area are for example configured to generate a sufficiently large height h1 of the SCR, for example greater than or equal to 10 nm and preferably greater than or equal to 15 nm. For example, via 340 is made of N-type doped monocrystalline or polycrystalline silicon with a dopant concentration in the range from 1e¹⁹ at·cm⁻³ to 4e²⁰ at·cm⁻³ and region 305 is doped with a dose in the range from 0.5e¹⁴ at·cm⁻² to 5e¹⁵ at·cm⁻².

At the step illustrated in FIGS. 3D and 3F, first area 330 is amorphous. The limit between first area 330 and the rest of region 305 thus forms an interface 350 between an amorphous area and a crystalline area of substrate 25.

As an example, amorphous areas 330 and 335 have a thickness h2 in the range from 10 nm to 150 nm. Preferably, amorphous areas 330 and 335 are entirely contained in the SCR.

FIG. 3G is a more detailed cross-section view of a portion of the structure of FIG. 3E. More particularly, FIG. 3G shows an enlarged view of the portion of FIG. 3E delimited by a frame in dashed lines in FIG. 3E.

FIG. 3G shows the p-n junction between via 340 and area 330 of region 305.

After the thermal anneal step, area 330 has become crystalline again and comprises, for example, few crystal defects.

Crystal defects 360 mainly form, for example, at interface 350. Crystal defects 360 form, for example, below interface 350, for example at the location of the deep defects generated by the ion implantation described in relation with FIG. 3C. Crystal defects 360 form in space charge region SCR and cause a leakage current in the p-n junction. The forming of crystal defects 360 improve the electrical conductivity of the electrical contact between each of vias 340 and 345 and first region 305. For example, point defects located in a neutral region, a region outside the space charge zone SCR, also contribute to increasing the leakage current of the p-n junction.

Crystal defects 360 are, for example, end-of-range defects, “311”-type defects or dislocations, for example dislocation loops or point defects (vacancy or interstitial).

In a subsequent step, not illustrated, an electrically-conductive track, for example the track 41 of FIG. 1, is formed, for example, at the surface of the device of FIG. 3F. The electrically-conductive track is in contact with at least one of vias 340 and 345 and is, for example, made of doped monocrystalline or polycrystalline silicon, having the same conductivity type as vias 340, 345.

There has been described in relation with FIGS. 3A to 3G an example of a method of forming second vias 39B of the device 11 of FIGS. 1 and 2, made of doped monocrystalline or polycrystalline silicon of the first conductivity type, that is, type N in the described example, in contact with second doped regions 305 of semiconductor substrate 25, of the second conductivity type, that is, type P in this example.

It should be noted that the same manufacturing steps may be simultaneously implemented opposite the first doped regions of the semiconductor substrate, of the first conductivity type, to form the first vias 39, also made of doped monocrystalline or polycrystalline silicon of the first conductivity type.

As an example, the implantation described in relation with FIG. 3C is local and only implemented in the areas where the second vias 39B are formed. For this purpose, a mask may be formed on the structure of FIG. 3C before the implantation, to mask (protect from implantation) the areas where the first vias 39A are formed.

As a variant, the implantation step described in relation with FIG. 3C is non-local, that is, the surface amorphization of the substrate is carried out not only opposite the openings intended to receive the second vias 39B, in the doped regions 305 of the second conductivity type, but also opposite the openings intended to receive first vias 39A, in the doped substrate regions of the first conductivity type.

The steps of forming of the first and second vias 39B are then entirely common, which enables to simplify the device manufacturing method.

In the example of FIGS. 3A to 3G, the recrystallization anneal of amorphous areas 330, 335 is implemented after the forming of monocrystalline or polycrystalline silicon vias 340, 345. As a variant, the recrystallization anneal may be implemented after the implantation and before the forming of vias 340, 345.

FIGS. 4A to 4F illustrate successive steps of another example of a method of manufacturing the device 11 of FIG. 1 and of FIG. 2, alternative to the method described in relation with FIGS. 3A to 3G, according to an embodiment of the present disclosure.

Certain elements of FIGS. 4A to 4F correspond to elements of FIGS. 1 to 3G. These elements are designated with the same references and will not be described again in detail.

FIGS. 4A to 4F illustrate the manufacturing of part only of the elements of the device 11 of FIGS. 1 and 2. FIGS. 4A to 4G more particularly show the forming of second doped monocrystalline or polycrystalline silicon vias 39B, of the first conductivity type, that is, type N in the described example, in contact with a doped second region 305 of semiconductor substrate 25, of the second conductivity type, that is, type P in this example.

FIG. 4A illustrates an example of an initial structure for the implementation of a method of manufacturing the device 11 of FIG. 1.

The structure of FIG. 4A comprises elements common with the structure of FIG. 3A, these elements being substantially arranged in the same way. The structure of FIG. 4A differs from the structure of FIG. 3A essentially in that it does not comprise upper dielectric layer 37.

The structure of FIG. 4A further comprises a mask 405 arranged at the surface of dielectric layer 29, for example on top of and in contact with the upper surface of dielectric layer 29. An opening 410 is formed in mask 405, for example by photolithography, to partially expose dielectric layer 29. Opening 410 is, for example, opposite region 305, for example between the first 310 and the second 315 shallow insulating trenches. As an example, the mask is made of resin or made of a tri-layer structure or made of a stack of a silicon nitride layer and a resin layer.

FIG. 4B shows the structure obtained after a step of ion implantation in region 305 of substrate 25, opposite opening 410.

During this step, ions are implanted in an upper portion of region 305 of substrate 25 opposite opening 410, according to a method similar to that described in relation with FIG. 3C. In the example of FIG. 4B, the ions are implanted through the opening 410 of mask 405 and through dielectric layer 29. The substrate regions covered by mask 405 are not implanted. Similar to what has been previously described, the ion implantation creates crystal defects and results in amorphizing a surface area 430 of region 305. Area 430 is in an upper portion of region 305. The ion implantation may further generate deep defects, in region 305 of substrate 25, below area 430.

Mask 405 is, for example, removed after the ion implantation.

As a variant, not illustrated, the implantation step is performed before a deposition step of the layer 29.

FIG. 4C shows the structure obtained after a step of deposition of dielectric layer 37 and of local etching of the openings 320, 325 intended to contain vias 39, from the upper surface of dielectric layer 37.

Dielectric layer 37 is, for example, deposited on top of and in contact with the upper surface of dielectric layer 29.

After the deposition of dielectric layer 37, openings 320, 325 are, for example, formed similarly to what has been described in relation with FIG. 3B.

In this example, openings 320, 325 emerge onto the upper surface of the amorphous upper layer 430 of region 305 of substrate 25.

As a variant, dielectric layer 29 is not present in the initial structure, mask 405 then being directly arranged on top of an oxide layer protecting the substrate 25. The thickness of the oxide layer is, for example, comprised in the range from 2 nm to 20 nm. The lower surface of the oxide layer is, for example, in contact with the upper surface of the substrate, and the upper surface of the oxide layer is in contact with the lower surface of the mask. In this case, layers 29 and 37 are successively formed on substrate 25 after the implantation step and the removal of mask 405, and before the forming of openings 320, 325.

FIG. 4D shows the structure obtained after a step of forming of the first via 340 and of the second via 345 respectively in the first opening 320 and in the second opening 325. This step is, for example, identical or similar to what has been previously described in relation with FIG. 3D.

In the example of FIG. 4D, a lower surface of via 340 and a lower surface of via 345 are in contact with an upper surface of amorphous area 430.

FIG. 4E shows the structure obtained after a step of thermal recrystallization anneal of area 430, for example identical or similar to the step described in relation with FIG. 3E. During the thermal anneal step, area 430 recrystallizes and crystal defects 460 form.

After the thermal anneal step, area 430, which has become crystalline again, for example comprises few crystal defects.

Defects 460 mainly form, for example, at an interface 450 between area 430 and substrate 25. Crystal defects 460 form, for example, under interface 450, for example at the location of the deep defects generated by the ion implantation. Defects 460 form, for example, in space charge region SCR and cause, for example, a leakage current at the level of the p-n junction.

The forming of defects 460 improves the electrical conductivity of the electrical contact between each of vias 340 and 345 and first region 305.

Crystal defects 460 are, for example, of the same type as the defects 360 described in relation with FIG. 3E.

In a subsequent step, an electrically-conductive track, for example the track 41 of FIG. 1, is formed, for example, at the surface of the device of FIG. 4E. The electrically-conductive track is in contact with at least one of vias 340 and 345 and is made, for example, of the same material as vias 340, 345, that is, made of doped monocrystalline or polycrystalline silicon.

In the example of FIGS. 4A to 4G, the recrystallization anneal of amorphous areas 430 is implemented after the forming of monocrystalline or polycrystalline silicon vias 340, 345. As a variant, the recrystallization anneal may be implemented after the implantation and before the forming of vias 340, 345. For example, the recrystallization anneal may be implemented after the step of forming of openings 320, 325 and before the step of forming of vias 340, 345. As a variant, the recrystallization anneal may be implemented after the step of deposition of dielectric layer 37 and before the forming of openings 320, 325. In another variant, the recrystallization anneal may be implemented before the step of deposition of dielectric layer 37.

An advantage of the method of FIGS. 4A to 4E is that area 430 has a more significant volume than each of the areas 330 and 335 of the method of FIGS. 3A to 3G. This results from the fact that, in the method of FIGS. 4A to 4E, the openings formed in implantation mask 405 have, in top view, a surface area larger than that of vias 39. The formation of crystal defects 460 is thus facilitated.

Although, in the examples described in relation with FIGS. 3A to 3G and 4A to 4E, the forming of two vias 340, 345 is detailed and illustrated, a single via or a number greater than two vias are, for example, simultaneously formed.

Further, although there has been described hereabove, in relation with FIG. 1, an example of an image acquisition device comprising two stacked image sensors, the manufacturing methods described in relation with FIGS. 3A to 3G and 4A to 4E may be used for the manufacturing of any electronic or optoelectronic device comprising a doped monocrystalline or polycrystalline silicon via of the first conductivity type forming an electrical contact area on a semiconductor layer or a doped semiconductor substrate of the second conductivity type.

For example, the above-described methods may be used to form an image acquisition device comprising an image sensor configured to be illuminated on the front surface, that is, in which, before reaching photosensitive areas formed in a semiconductor substrate of the sensor, light crosses an interconnection stack coating the substrate. In this case, the levels of vias and conductive tracks of the interconnection stack closest to the semiconductor substrate may be formed with doped monocrystalline or polycrystalline silicon by the above-described methods.

The above-described methods may further be used to form an electronic chip comprising a first doped monocrystalline or polycrystalline silicon interconnection level, for example to avoid the use of metal in methods of manufacturing this first level, so as to, for example, avoid possible metal contaminations of the chip or of the chip manufacturing equipment.

In the above-described examples, region 305 of substrate 25 corresponds, for example, to a source or drain region of a transistor.

An advantage of the various provided embodiments is to allow the simultaneous forming of doped monocrystalline or polycrystalline silicon contacting vias, respectively on first doped regions of substrate 25 of a first conductivity type and on second doped regions of the substrate of a second conductivity type opposite to the first type. This enables to save time and materials and to decrease the manufacturing cost. When the monocrystalline or polycrystalline silicon vias are used to make electrical contact on a region of the substrate of a conductivity type opposite to that of the via, the ion implantation followed by a thermal recrystallization anneal degrades the p-n junction formed at the interface between the via and the substrate, and thus increases the conductivity of the electrical contact.

Various embodiments and variants have been described. Those skilled in the art will understand that certain features of these various embodiments and variants may be combined, and other variants will occur to those skilled in the art. In particular, although examples of embodiment where all monocrystalline or polycrystalline silicon vias are N-type doped, as a variant, all monocrystalline or polycrystalline silicon vias may be P-type doped.

Finally, the practical implementation of the described embodiments and variants is within the abilities of those skilled in the art based on the functional indications given hereabove.

1. A method of manufacturing an electronic device, comprising the following steps:
a) forming, in an upper surface side of a semiconductor substrate, first doped regions of a first conductivity type and second doped regions of a second conductivity type opposite to the first type;
b) after step a), depositing a dielectric layer on the upper surface of the substrate;
c) after step b), forming first and second openings in dielectric layer to respectively expose the first and second regions of the substrate;
d) implanting non-doping ions in the second regions to amorphize an upper portion of the second regions;
e) after steps c) and d), filling the first and second openings with doped monocrystalline or polycrystalline silicon of the first conductivity type to form contacting vias on the first and second regions; and
f) performing a thermal anneal to recrystallize said upper portion of the second regions.

2. The method according to claim 1, wherein, at the end of step f), crystal defects are generated in a space charge region of a p-n junction formed at the interface between the vias and the second regions.

3. The method according to claim 1, wherein, at the end of step f), crystal defects are generated outside and within 100 nm of the space charge region.

4. The method according to claim 1, wherein step d) is carried out after step c).

5. The method according to claim 1, wherein step d) is carried out between step a) and step b).

6. The method according to claim 1, wherein step f) is carried out after step e).

7. The method according to claim 1, further comprising a step of depositing an electrically-conductive layer made of doped monocrystalline or polycrystalline silicon of the first conductivity type on top of and in contact with the surface of the vias opposite to the first and second regions of the substrate.

8. The method according to claim 1, wherein the non-doping ions are selected from the group consisting of germanium, argon, carbon, or silicon ions.

9. The method according to claim 1, wherein the substrate is made of silicon.

10. The method according to claim 1, wherein the thermal anneal is performed at temperature in the range from 800° C. to 1,000° C.

11. An electronic device, comprising:
a semiconductor substrate;
first doped regions of a first conductivity type and second doped regions of a second conductivity type opposite to the first type on the upper surface side of the substrate;
a dielectric layer coating the upper surface of the substrate;
doped monocrystalline or polycrystalline silicon vias of the first conductivity type extending through the dielectric layer to make electrical contact on the first and second regions.

12. The device according to claim 11, further comprising an electrically-conductive layer made of doped monocrystalline silicon or polycrystalline silicon of the first conductivity type, wherein the electrically-conductive layer is located on top of and in contact with a surface of the vias opposite to the first region and second region of the substrate.

13. An image sensor comprising the electronic device according to claim 11.

14. The image sensor according to claim 13, configured to be illuminated on a front surface corresponding to a side of the substrate in contact with the vias.

15. The image sensor according to claim 13, wherein the image sensor is is a visible image sensor.

16. An imaging system comprising first and second image sensors vertically stacked on each other, wherein:
the first image sensor is the image sensor according to claim 14; and
the second image sensor is arranged on a front surface corresponding to a side of the substrate in contact with the vias.

17. The imaging system according to claim 16, wherein the first image sensor is a visible image sensor and the second image sensor is an infrared image sensor.
